(19) United States
(12) Patent Application Publication
(10) Pub. No.: US 2017/0345754 A1
(43) Pub. Date: Nov. 30, 2017

(54) THREE-DIMENSIONAL INDUCTOR STRUCTURE AND STACKED SEMICONDUCTOR DEVICE INCLUDING THE SAME

(71) Applicant: Samsung Electronics Co., Ltd., Suwon-si (KR)

(72) Inventors: Won-Joo YUN, Yongin-si (KR); Suk-Yong KANG, Suwon-si (KR); Sang-Hoon SHIN, Yongin-si (KR); Hye-Seung YU, Goyang-si (KR); Hyun-Ui LEE, Osan-si (KR); Jae-Hun JUNG, Seoul (KR)

(21) Appl. No.: 15/396,633

(22) Filed: Dec. 31, 2016

(30) Foreign Application Priority Data
May 25, 2016 (KR) 10-2016-0063983

(51) Int. Cl. H01L 23/522; H01L 23/525; H01L 25/065; H02J 50/12; H01L 23/528; H01L 23/48

(52) U.S. Cl. CPC H01L 23/5227; H01L 23/528; H01L 23/481; H01L 25/0657; H02J 50/12; H01L 23/5256; H01L 2225/06524; H01L 2225/06541

(57) ABSTRACT

A three-dimensional (3D) inductor structure comprising: a first semiconductor die including: a first conductive pattern; and a second conductive pattern spaced apart from the first conductive pattern; a second semiconductor die stacked on the first semiconductor die, the second semiconductor die including: a third conductive pattern; a fourth conductive pattern spaced apart from the third conductive pattern; a first through-substrate via (TSV) penetrating the second semiconductor die and electrically connecting the first conductive pattern with the third conductive pattern; and a second TSV penetrating the second semiconductor die and electrically connecting the second conductive pattern with the fourth conductive pattern, and a first conductive connection pattern included in the first semiconductor die and electrically connecting a first end of the first conductive pattern with a first end of the second conductive pattern, or included in the second semiconductor die and electrically connecting a first end of the third conductive pattern with a first end of the fourth conductive pattern.

### CROSS-REFERENCE TO RELATED APPLICATION

This application claims priority under 35 USC §119 to Korean Patent Application No. 10-2016-0063983, filed on May 25, 2016 in the Korean Intellectual Property Office (KIPO), the contents of which are herein incorporated by reference in their entirety.

### BACKGROUND

### 1. Technical Field

Embodiments relate generally to semiconductor elements, and more particularly to three-dimensional (3D) inductor structures and stacked semiconductor devices including the 3D inductor structures.

### 2. Description of the Related Art

Various techniques for increasing the degree of integration of semiconductor devices have been developed. For example, since the semiconductor device includes a plurality of components, e.g., transistors, diodes, resistors, capacitors, inductors, etc., the larger number of components may be integrated into one semiconductor device for increasing the degree of integration. For another example, a stacked semiconductor device, in which semiconductor dies including components are stacked on each other, may be manufactured for increasing the degree of integration.

### SUMMARY

Embodiments include a three-dimensional (3D) inductor structure comprising: a first semiconductor die including: a first conductive pattern; and a second conductive pattern spaced apart from the first conductive pattern; a second semiconductor die stacked on the first semiconductor die, the second semiconductor die including: a third conductive pattern; a fourth conductive pattern spaced apart from the third conductive pattern; a first through-substrate via (TSV) penetrating the second semiconductor die and electrically connecting the first conductive pattern with the third conductive pattern; and a second TSV penetrating the second semiconductor die and electrically connecting the second conductive pattern with the fourth conductive pattern, and a first conductive connection pattern included in the first semiconductor die and electrically connecting a first end of the first conductive pattern with a first end of the second conductive pattern, or included in the second semiconductor die and electrically connecting a first end of the third conductive pattern with a first end of the fourth conductive pattern.

Embodiments include a stacked semiconductor device comprising: a first semiconductor die including: a first conductive pattern; a second conductive pattern spaced apart from the first conductive pattern; a first conductive connection pattern electrically connecting a first end of the first conductive pattern with a first end of the second conductive pattern; and a first functional circuit; and a plurality of second semiconductor dies sequentially stacked on the first semiconductor die, each of the second semiconductor dies including: a plurality of third conductive patterns; a plurality of fourth conductive patterns spaced apart from the third conductive patterns; a first through-substrate via (TSV) penetrating each of the second semiconductor dies; a second TSV penetrating each of the second semiconductor dies; and a second functional circuit; wherein: a first selection pattern among the third conductive patterns is electrically connected to the first conductive pattern by the first TSV; and a second selection pattern among the plurality of fourth conductive patterns is electrically connected to the second conductive pattern by the second TSV.

Embodiments include a stacked semiconductor device comprising: a plurality of semiconductor dies; a plurality of through-substrate vias (TSV) penetrating at least one of the semiconductor dies; a plurality of conductive patterns, wherein each of the semiconductor dies includes at least two of the conductive patterns; and a first conductive connection pattern included in one of the semiconductor dies that electrically connects a first two of the conductive patterns; wherein: each of the TSVs electrically connects a corresponding second two of the conductive patterns; and the TSVs, the conductive patterns, and the first conductive connection pattern are electrically connected in series.

### BRIEF DESCRIPTION OF THE DRAWINGS

Embodiments will be more clearly understood from the following detailed description taken in conjunction with the accompanying drawings.

FIG. 1 is a perspective view of a three-dimensional (3D) inductor structure according to some embodiments.

FIGS. 2A and 2B are diagrams for describing the 3D inductor structure of FIG. 1.

FIG. 3 is a perspective view of a 3D inductor structure according to some embodiments.

FIG. 4 is a diagram for describing the 3D inductor structure of FIG. 3.

FIG. 5 is a perspective view of a 3D inductor structure according to some embodiments.

FIGS. 6A and 6B are diagrams for describing the 3D inductor structure of FIG. 5.

FIG. 7 is a perspective view of a 3D inductor structure according to some embodiments.

FIG. 8 is a diagram for describing the 3D inductor structure of FIG. 7.

FIG. 9A is a plan view of a stacked semiconductor device according to some embodiments.

FIG. 9B is a cross-sectional view of the stacked semiconductor device taken along a line III-III′ of FIG. 9A.

FIG. 10A is a plan view of a stacked semiconductor device according to some embodiments.

FIG. 10B is a cross-sectional view of the stacked semiconductor device taken along a line IV-IV′ of FIG. 10A.

FIG. 11 is a block diagram illustrating a data transceiving system according to some embodiments.

FIG. 12 is a block diagram illustrating a test system according to some embodiments.

FIG. 13 is a block diagram illustrating a wireless power transmission system according to some embodiments.

FIG. 14 is a diagram illustrating an example of the wireless power transmission system of FIG. 13.

FIG. 15 is a block diagram illustrating a mobile system according to some embodiments.

### DETAILED DESCRIPTION OF THE EMBODIMENTS

Embodiments will be described more fully with reference to the accompanying drawings, in which embodiments are shown. Embodiments may, however, take many different forms and should not be construed as limited to the particular embodiments set forth herein. Like reference numerals refer to like elements throughout this application.

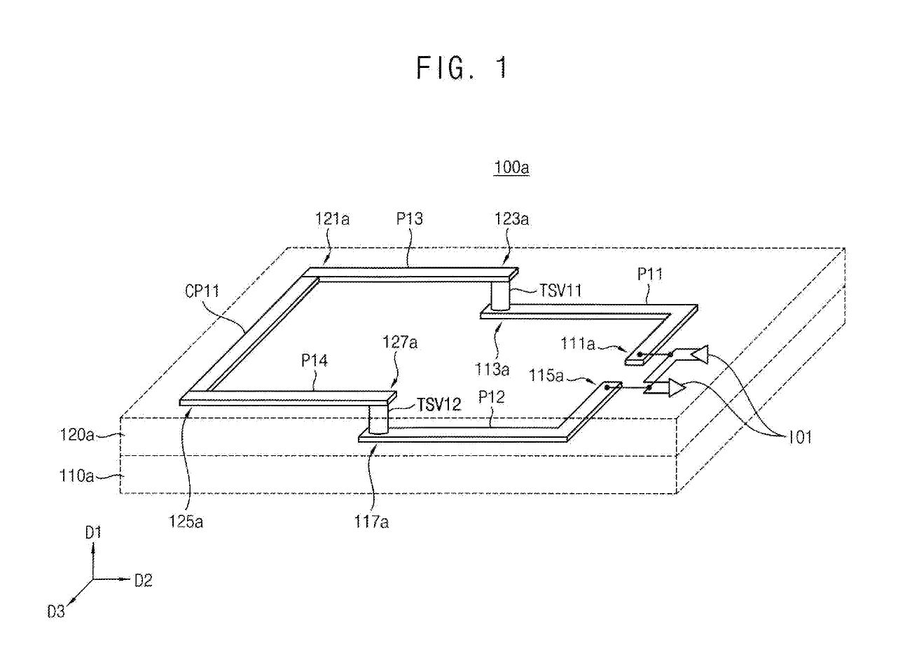

FIG. 1 is a perspective view of a three-dimensional (3D) inductor structure according to some embodiments. In FIG. 1, a direction substantially vertical to a first surface (e.g., a top surface) of a semiconductor die is referred to as a first direction D1 (e.g., a Z-axis direction). In addition, two directions substantially parallel to the first surface of the semiconductor die and crossing each other are referred to as a second direction D2 (e.g., a X-axis direction) and a third direction D3 (e.g., a Y-axis direction). For example, the second and third directions D2 and D3 may be substantially perpendicular to each other. In addition, the first direction D1 is substantially perpendicular to both the second direction D2 and the third direction D3. Additionally, a direction indicated by an arrow in the figures and a reverse direction thereof are considered as the same direction. The definition of the first, second and third directions D1, D2 and D3 are same in the figures cited in this disclosure.

A three-dimensional (3D) inductor structure 100a includes a first semiconductor die 110a, a second semiconductor die 120a and a first conductive connection pattern CP11. The 3D inductor structure 100a may further include an input/output (I/O) unit IO1.

The first semiconductor die 110a includes a first conductive pattern P11 and a second conductive pattern P12 that is spaced apart from the first conductive pattern P11. The first semiconductor die 110a may be referred to as a lower semiconductor die or a bottom semiconductor die.

In some embodiments, a first conductive layer may be disposed on a first substrate and may be etched to form the conductive patterns P11 and P12, and thus the first semiconductor die 110a may be formed. A semiconductor substrate including crystalline silicon formed of a single crystal and/or crystalline germanium formed of a single crystal may be used as the first substrate. For example, the first substrate may be obtained from a silicon wafer. The first conductive layer may include a metal, a metal nitride or doped polysilicon by, e.g., an atomic layer deposition (ALD) process or a sputtering process.

Although not illustrated in FIG. 1, a first insulation layer may be disposed on the first substrate on which the conductive patterns P11 and P12 are formed. The first insulation layer may be formed of silicon oxide or a metal oxide by, for example, a chemical vapor deposition (CVD) process, a plasma enhanced chemical vapor deposition (PECVD) process, a spin coating process, an ALD process, etc. In addition, the first insulation layer may be formed by a thermal oxidation process on a top surface of the first substrate.

The second semiconductor die 120a is stacked on the first semiconductor die 110a. The second semiconductor die 120a includes a third conductive pattern P13, a fourth conductive pattern P14, a first through-substrate via (TSV) TSV11 and a second TSV TSV12. The fourth conductive pattern P14 is spaced apart from the third conductive pattern P13. The first TSV TSV11 penetrates (e.g., extends through) the second semiconductor die 120a and electrically connects the first conductive pattern P11 with the third conductive pattern P13. The second TSV TSV12 penetrates the second semiconductor die 120a and electrically connects the second conductive pattern P12 with the fourth conductive pattern P14. The second semiconductor die 120a may be referred to as an upper semiconductor die or a top semiconductor die.

The first conductive connection pattern CP11 electrically and directly connect a first end 121a of the third conductive pattern P13 with a first end 125a of the fourth conductive pattern P14.

In some embodiments, a second conductive layer may be disposed on a second substrate and may be etched to form the conductive patterns P13, P14 and CP11. In addition, trenches may be formed to penetrate the second substrate, and the TSVs TSV11 and TSV12 may be formed by filling the trenches with conductive material, and thus the second semiconductor die 120a may be formed. For example, the conductive material may include metal such as copper, aluminum, tungsten, doped polysilicon, or the like.

In some embodiments, the TSVs TSV11 and TSV12 may be formed in advance and then the conductive patterns P13, P14 and CP11 may be formed. In other some embodiments, the conductive patterns P13, P14 and CP11 may be formed in advance and then the TSVs TSV11 and TSV12 may be formed.

The I/O unit IO1 may be included in the first semiconductor die 110a. The I/O unit IO1 may be electrically connected to a first end 111a of the first conductive pattern P11 and a first end 115a of the second conductive pattern P12. Although a particular circuit is illustrated, in other embodiments, the circuit may be different.

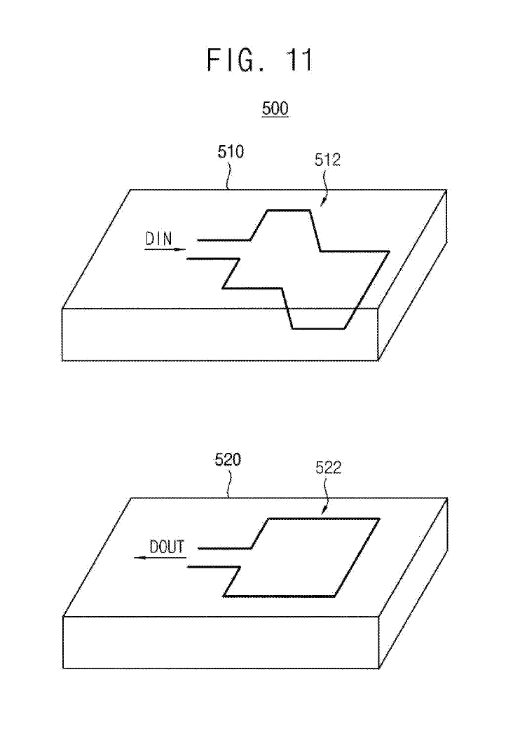

In some embodiments, a coil may be formed by electrical connections of the conductive patterns P11, P12, P13, P14 and CP11 and the TSVs TSV11 and TSV12. As will be described with reference to FIGS. 11, 12, 13 and 14, the coil may be used for transmitting or receiving data and/or power, and the I/O unit IO1 may provide an electrical signal to the coil for the data and/or power transceiving. For example, the I/O unit IO1 may be an inductive coupling I/O unit.

In some embodiments, the first TSV TSV11 may be electrically and directly connected to a second end 113a of the first conductive pattern P11 and a second end 123a of the third conductive pattern P13. The second TSV TSV12 may be electrically and directly connected to a second end 117a of the second conductive pattern P12 and a second end 127a of the fourth conductive pattern P14.

Although FIG. 1 illustrates that the conductive patterns P13, P14 and CP11 are physically separated from one another, the conductive patterns P13, P14 and CP11 may not be physically separated and may be a single continuous conductive pattern for forming the coil.

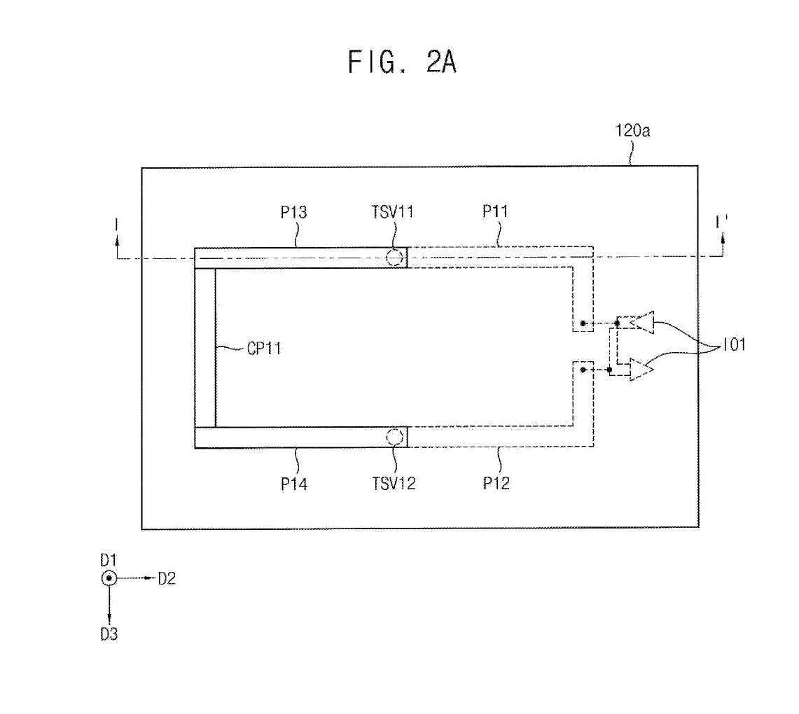

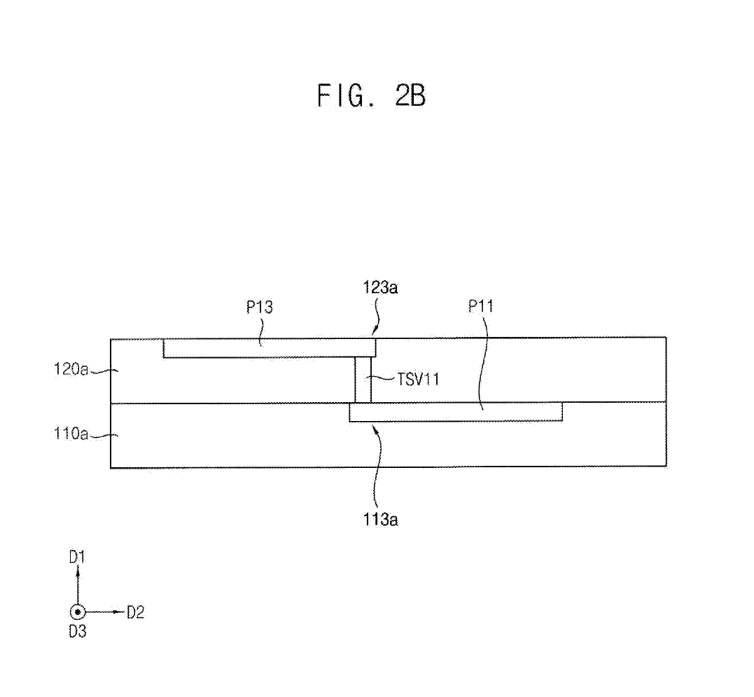

FIGS. 2A and 2B are diagrams for describing the 3D inductor structure of FIG. 1. FIG. 2A is a plan view of the 3D inductor structure of FIG. 1. FIG. 2B is a cross-sectional view of the 3D inductor structure taken along a line I-I′ of FIG. 2A. Referring to FIGS. 1 and 2A, in a plan view of the 3D inductor structure 100a including the first and second semiconductor dies 110a and 120a (e.g., as seen in the first direction D1), the coil formed by the conductive patterns P11, P12, P13, P14 and CP11 and the TSVs TSV11 and TSV12 may have a shape in which a portion of a closed curve is open. For example, the portion of the coil in which the closed curve is open may be between the first end 111a of the first conductive pattern P11 and the first end 115a of the second conductive pattern P12.

In some embodiments, as illustrated in FIGS. 1 and 2A, each of the first and second conductive patterns P11 and P12 may have an L shape that extends in the second and third directions D2 and D3. Each of the third and fourth conductive patterns P13 and P14 may have a linear shape that extends in the second direction D2. The first conductive connection pattern CP11 may have a linear shape that extends in the third direction D3.

In other some embodiments, although not illustrated in FIGS. 1 and 2A, each of the conductive patterns may have any shape such that a coil formed by the conductive patterns has a shape in which a portion of a closed curve is open.

Referring to FIGS. 1 and 2B, in a cross-sectional view of the 3D inductor structure 100a including the first and second semiconductor dies 110a and 120a (e.g., as seen in the third direction D3), the first conductive pattern P11, the first TSV TSV11 and the third conductive pattern P13 may be formed to have a stepped structure or a terraced structure. In other words, in a cross-sectional view, the conductive patterns P11 and P13 may be disposed or arranged scalariformly, e.g., in a step shape. Similarly, in a cross-sectional view, the second conductive pattern P12, the second TSV TSV12 and the fourth conductive pattern P14 may be formed to have a stepped structure or a terraced structure.

In some embodiments, as illustrated in FIGS. 1 and 2B, the first conductive pattern P11 and the third conductive pattern P13 may partially overlap each other, and the first TSV TSV11 may directly connect the first conductive pattern P11 with the third conductive pattern P13. For example, the second end 113a of the first conductive pattern P11 and the second end 123a of the third conductive pattern P13 may overlap each other, and the first TSV TSV11 may directly connect the second end 113a of the first conductive pattern P11 with the second end 123a of the third conductive pattern P13. Similarly, the second conductive pattern P12 and the fourth conductive pattern P14 may partially overlap each other, and the second TSV TSV12 may directly connect the second conductive pattern P12 with the fourth conductive pattern P14.

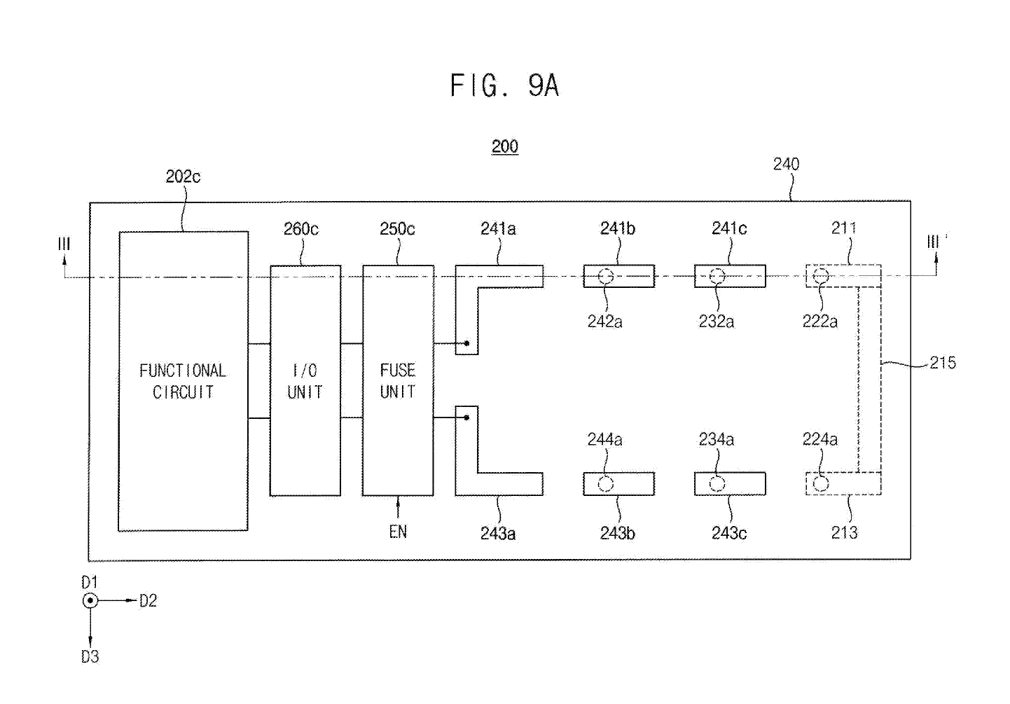

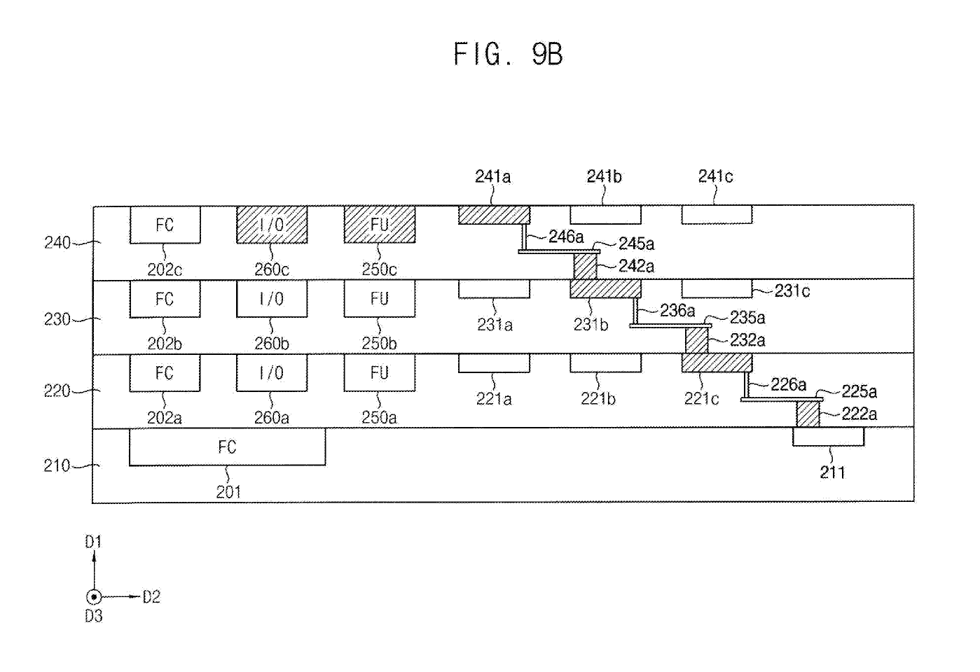

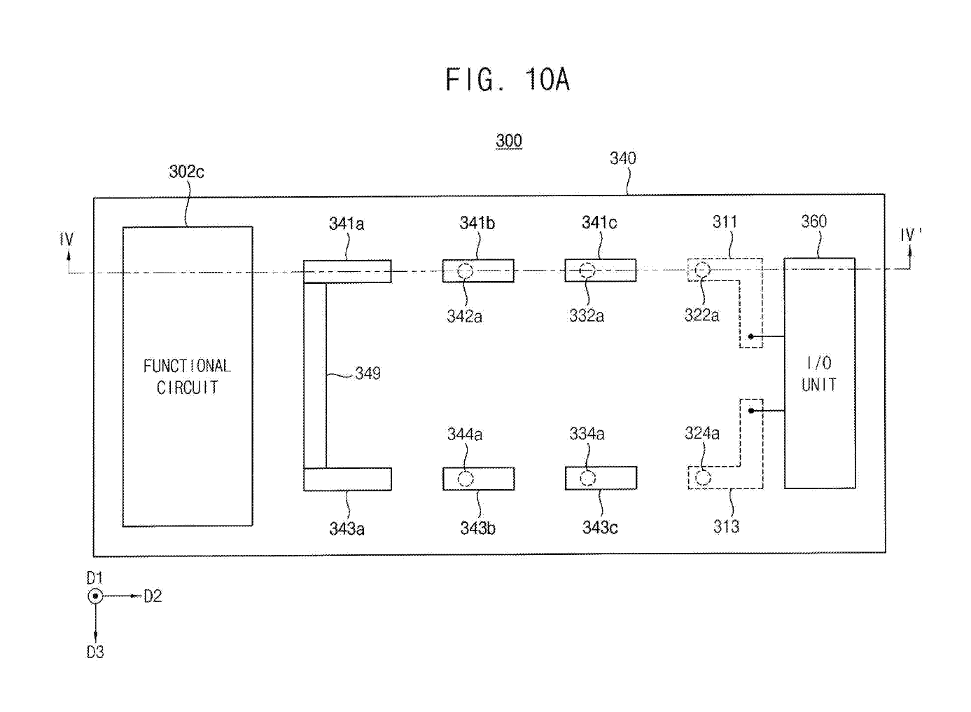

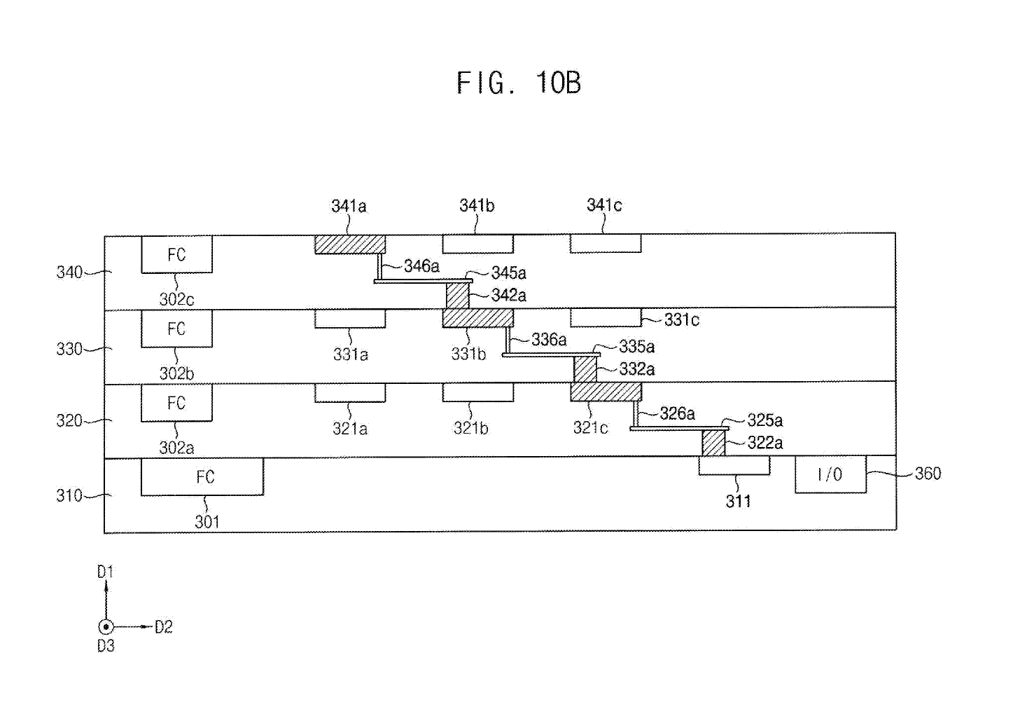

In other embodiments, although not illustrated in FIGS. 1 and 2B, the first conductive pattern and the third conductive pattern may not overlap each other. In this example, as will be described with reference to FIGS. 9B and 10B, the second semiconductor die 120a may further include at least one wiring and at least one contact (or plug), and the first conductive pattern and the third conductive pattern may be connected to each other by the first TSV TSV11, the at least one wiring and the at least one contact.

In some embodiments, as illustrated in FIGS. 1 and 2B, each of the conductive patterns P11, P12, P13, P14 and CP11 may have a uniform thickness. Each of the TSVs TSV11 and TSV12 may have a cylindrical shape, and a size of a bottom surface and a size of a top surface in each TSV may be substantially the same as each other.

In other embodiments, although not illustrated in FIGS. 1 and 2B, each conductive pattern may have a non-uniform thickness. Each TSV may have any pillar or column shape, and a size of a bottom surface, and a size of a top surface in each TSV may be different from each other.

The 3D inductor structure 100a according to some embodiments may be implemented as a 3D structure based on the conductive patterns P11, P12, P13, P14 and CP11 and the TSVs TSV11 and TSV12 that are included in the stacked semiconductor dies 110a and 120a. Accordingly, the 3D inductor structure 100a may have a relatively small size and may be more easily manufactured.

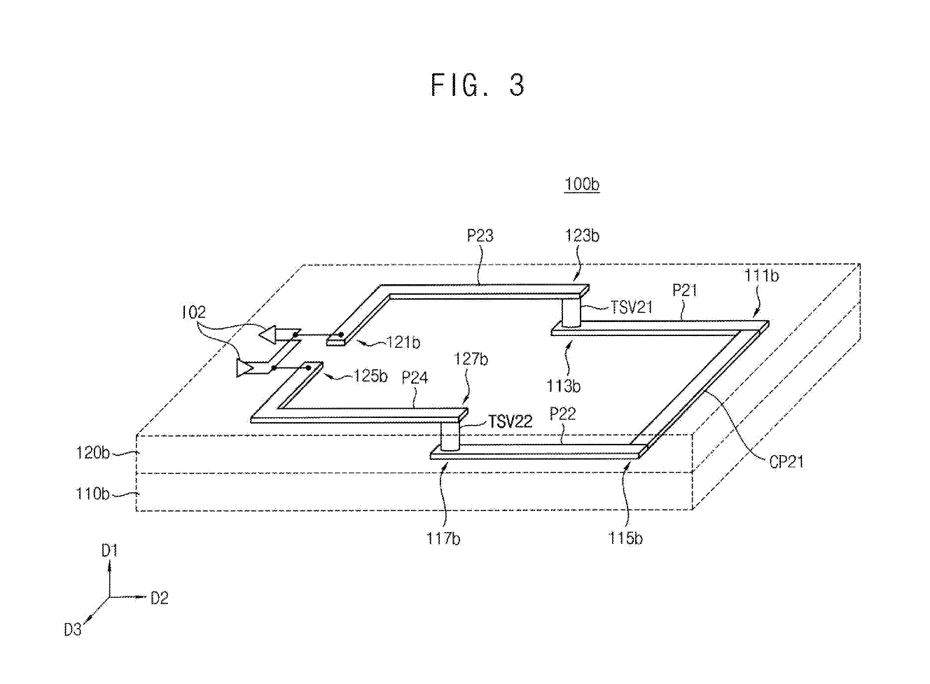

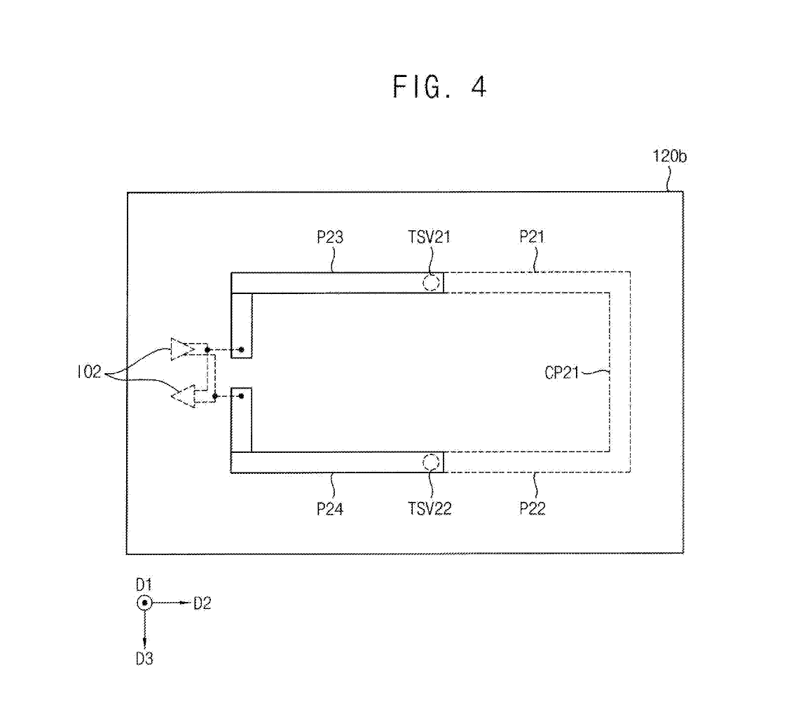

FIG. 3 is a perspective view of a 3D inductor structure according to some embodiments. FIG. 4 is a diagram for describing the 3D inductor structure of FIG. 3. FIG. 4 is a plan view of the 3D inductor structure of FIG. 3. Referring to FIGS. 3 and 4, a 3D inductor structure 100b includes a first semiconductor die 110b, a second semiconductor die 120b and a first conductive connection pattern CP21. The 3D inductor structure 100b may further include an I/O unit 102.

The 3D inductor structure 100b of FIGS. 3 and 4 may be substantially the same as the 3D inductor structure 100a of FIG. 1, except that arrangements and connections of the first conductive connection pattern CP21 and the I/O unit 102 are changed. For example, the conductive patterns P21, P22, P23, and P24 with ends 111b, 113b, 115b, 117b, 121b, 123b, 125b, and 127b, the TSVs TSV21 and TSV22, the conductive pattern CP21, the I/O unit 102 may be similar to the corresponding structures of the 3D inductor structure 100a, described above. However, the I/O unit 102 is formed in the second semiconductor die 120b and the conductive pattern P21, P22, P23, and P24 and the conductive pattern CP21 may be formed in a different semiconductor die.

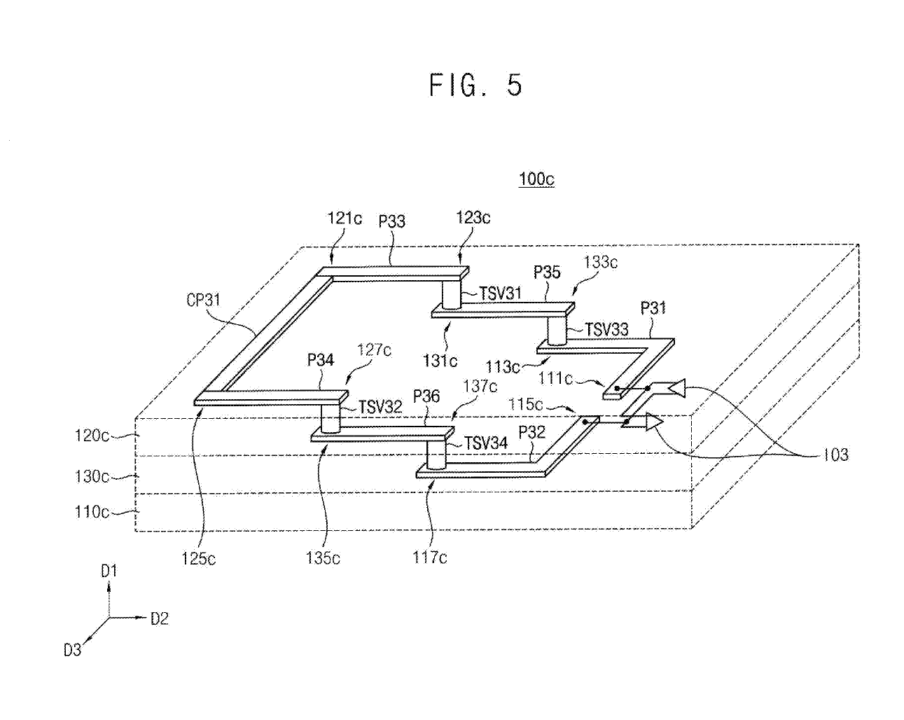

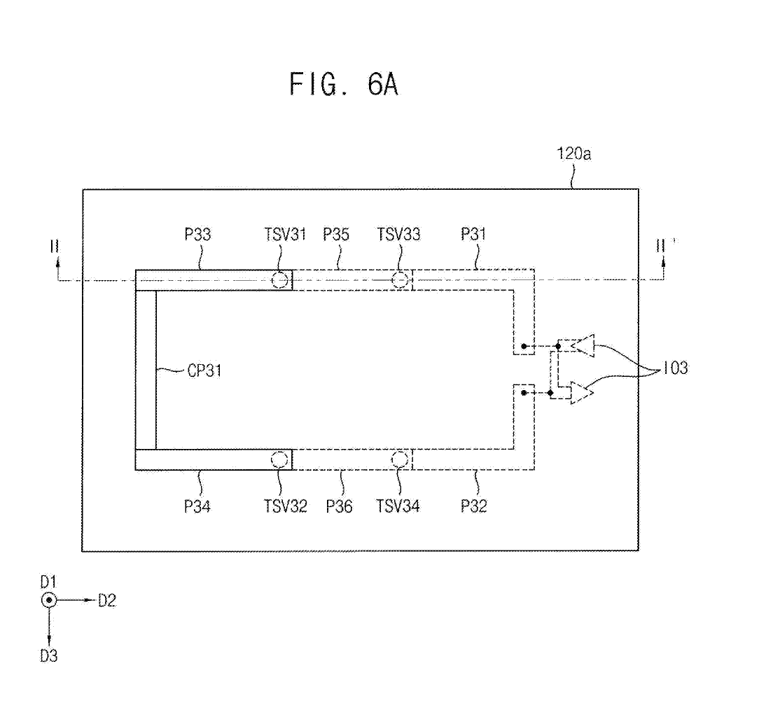

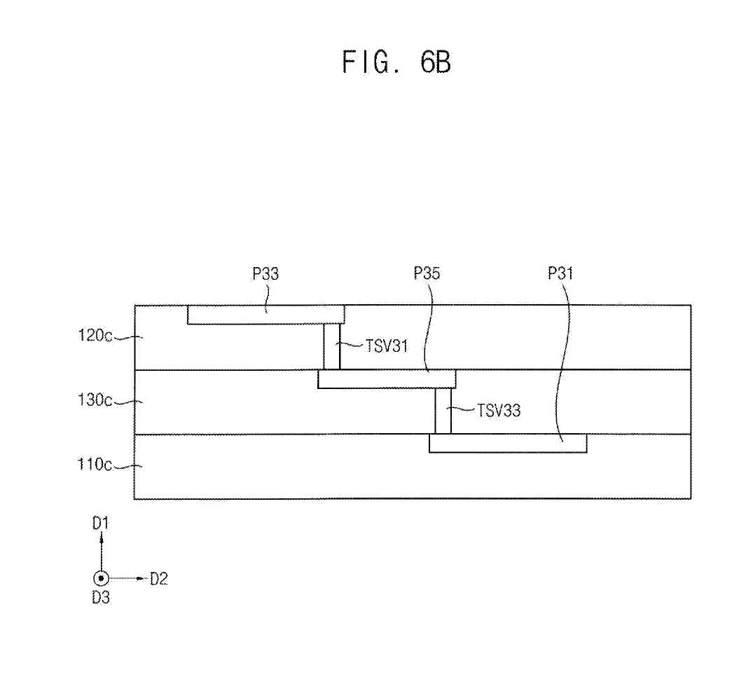

FIG. 5 is a perspective view of a 3D inductor structure according to some embodiments. FIGS. 6A and 6B are diagrams for describing the 3D inductor structure of FIG. 5. FIG. 6A is a plan view of the 3D inductor structure of FIG. 5. FIG. 6B is a cross-sectional view of the 3D inductor structure taken along a line II-II′ of FIG. 6A.

Referring to FIGS. 5, 6A and 6B, a 3D inductor structure 100c includes a first semiconductor die 110c, a second semiconductor die 120c and a first conductive connection pattern CP31. The 3D inductor structure 100c may further include a third semiconductor die 130c and an I/O unit 103.

The 3D inductor structure 100c of FIG. 5 may be substantially the same as the 3D inductor structure 100a of FIG. 1, except that the 3D inductor structure 100c further includes the third semiconductor die 130c. For example, the conductive patterns P31, P32, P33, and P34 with ends 111c, 113c, 115c, 117c, 121c, 123c, 125c, and 127c, the conductive pattern CPc1, the I/O unit 103 may be similar to the corresponding structures of the 3D inductor structure 100a or 100b, described above.

The TSVs TSV31, TSV32, TSV33, and TSV34 may be similar to the corresponding TSVs TSV11, TSV12, TSV21, and TSV22. However, the TSVs TSV31, TSV32, TSV33, and TSV34 may penetrate different semiconductor dies. In particular, the third semiconductor die 130c may be disposed between the first semiconductor die 110c and the second semiconductor die 120c. The third semiconductor die 130c may include a fifth conductive pattern P35, a sixth conductive pattern P36. The sixth conductive pattern P36 may be spaced apart from the fifth conductive pattern P35. The third and fourth TSVs TSV33 and TSV34 may penetrate the third semiconductor die 130c. The third semiconductor die 130c may be referred to as a middle semiconductor die.

In contrast, to the 3D inductor structures 100a and 100b, described above, the 3D inductor structure 100c electrically connects the conductive patterns P31, P32, P33, and P34 using the four TSVs TSV31, TSV32, TSV33, and TSV34 and the fifth and sixth conductive patterns P35 and P36.

Although FIG. 5 illustrates an example where one semiconductor die 130c is disposed between the first and second semiconductor dies 110c and 120c, a 3D inductor structure according to some embodiments may further include more than two middle semiconductor dies that are disposed between the first semiconductor die 110c (e.g., the bottom semiconductor die) and the second semiconductor die 120c (e.g., the top semiconductor die). As described above, in a plan view, a coil formed by conductive patterns in the semiconductor dies may have a shape in which a portion of a closed curve is open. In addition, in a cross-sectional view, the conductive patterns and TSVs in the semiconductor dies may be formed to have a stepped structure or a terraced structure.

Although FIG. 5 illustrates an example where the first conductive connection pattern CP31 is included in the second semiconductor die 120c and the I/O unit 103 is included in the first semiconductor die 110c, a 3D inductor structure according to some embodiments may include a first conductive connection pattern that is included in the first semiconductor die 110c and an I/O unit that is included in the second semiconductor die 120c, similar to that illustrated in FIG. 3.

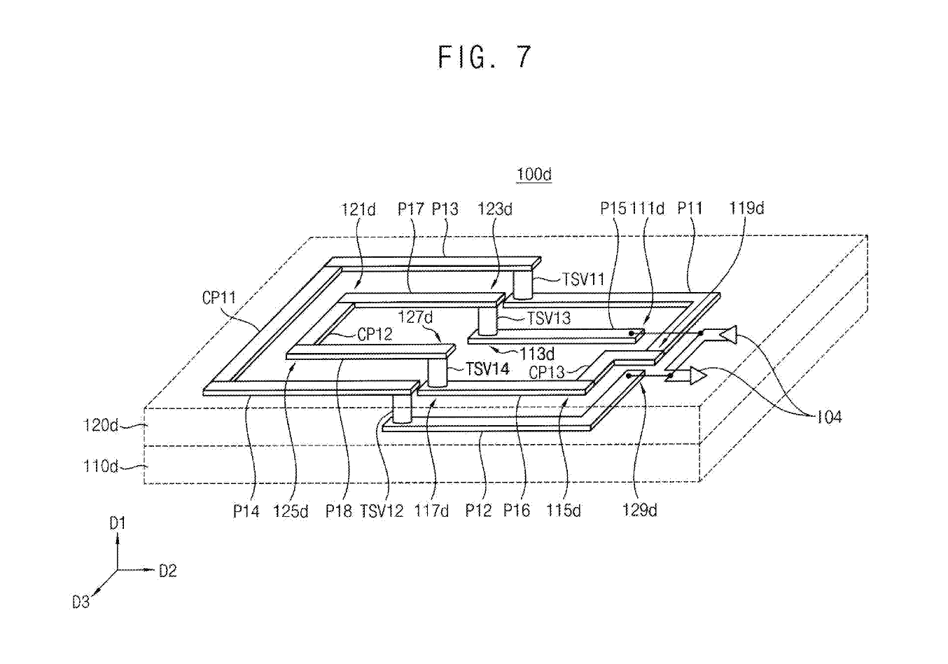

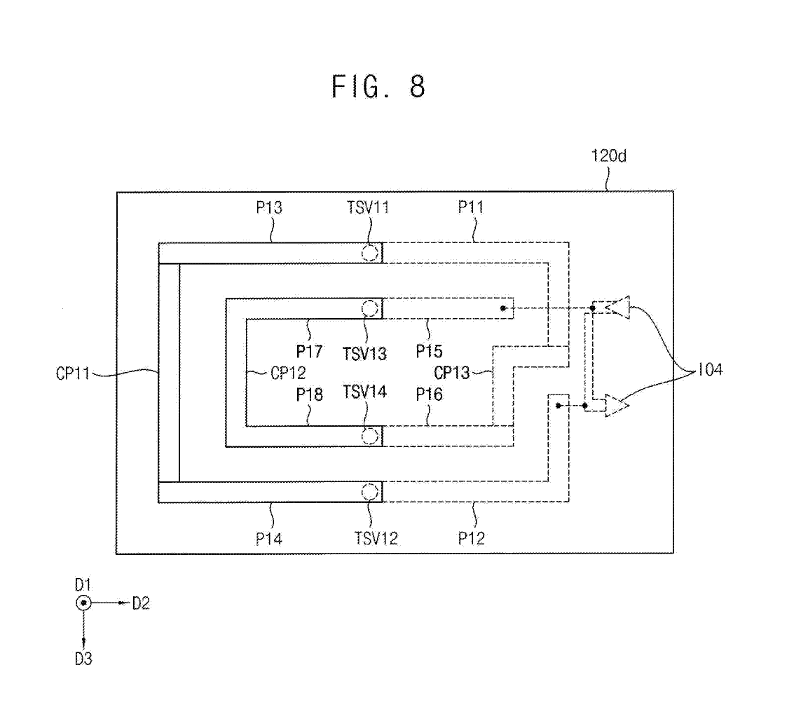

FIG. 7 is a perspective view of a 3D inductor structure according to some embodiments. FIG. 8 is a diagram for describing the 3D inductor structure of FIG. 7. FIG. 8 is a plan view of the 3D inductor structure of FIG. 7. Referring to FIGS. 7 and 8, a 3D inductor structure 100d includes a first semiconductor die 110d, a second semiconductor die 120d and a first conductive connection pattern CP11. The 3D inductor structure 100d may further include a second conductive connection pattern CP12, a third conductive connection pattern CP13 and an I/O unit 104.

The 3D inductor structure 100d of FIG. 7 may be substantially the same as the 3D inductor structure 100a of FIG. 1, except that the 3D inductor structure 100d further includes conductive patterns P15, P16, P17 and P18, the conductive connection patterns CP12 and CP13 and TSVs TSV13 and TSV14.

The first semiconductor die 110d includes a first conductive pattern P11 and a second conductive pattern P12. The second semiconductor die 120d is stacked on the first semiconductor die 110d and includes a third conductive pattern P13, a fourth conductive pattern P14, a first TSV TSV11 and a second TSV TSV12. The first conductive connection pattern CP11 is included in the second semiconductor die 120d. Arrangements and connections of the conductive patterns P11, P12, P13, P14 and CP11 and the TSVs TSV11 and TSV12 may be substantially the same as those of the conductive patterns P11, P12, P13, P14 and CP11 and the TSVs TSV11 and TSV12 in FIGS. 1, 2A and 2B.

The first semiconductor die 110d may further include a fifth conductive pattern P15 and a sixth conductive pattern P16. The fifth conductive pattern P15 may be spaced apart from the first and second conductive patterns P11 and P12. The sixth conductive pattern P16 may be spaced apart from the first, second and fifth conductive patterns P11, P12 and P15.

The second semiconductor die 120d may further include a seventh conductive pattern P17, an eighth conductive pattern P18, a third TSV TSV13 and a fourth TSV TSV14. The seventh conductive pattern P17 may be spaced apart from the third and fourth conductive patterns P13 and P14. The eighth conductive pattern P18 may be spaced apart from the third, fourth and seventh conductive patterns P13, P14 and P17. The third TSV TSV13 may penetrate the second semiconductor die 120d and may electrically connect the fifth conductive pattern P15 with the seventh conductive pattern P17. The fourth TSV TSV14 may penetrate the second semiconductor die 120d and may electrically connect the sixth conductive pattern P16 with the eighth conductive pattern P18.

The second conductive connection pattern CP12 may be included in the second semiconductor die 120d to electrically and directly connect a first end 121d of the seventh conductive pattern P17 with a first end 125d of the eighth conductive pattern P18. The third conductive connection pattern CP13 may be included in the first semiconductor die 110d to electrically and directly connect the first end 119d of the first conductive pattern P11 with a first end 115d of the sixth conductive pattern P16. The I/O unit 104 may be included in the first semiconductor die 110d and may be electrically connected to the first end 129d of the second conductive pattern P12 and a first end 111d of the fifth conductive pattern P15. The third TSV TSV13 may electrically and directly connect a second end 113d of the fifth conductive pattern P15 with a second end 123d of the seventh conductive pattern P17. The fourth TSV TSV14 may electrically and directly connect a second end 117d of the sixth conductive pattern P16 with a second end 127d of the eighth conductive pattern P18.

In some embodiments, in a plan view of the 3D inductor structure 100d including the semiconductor dies 110d and 120d, a first coil may be formed by the conductive patterns P11, P12, P13, P14 and CP11 and the TSVs TSV11 and TSV12, and a second coil may be formed by the conductive patterns P15, P16, P17, P18 and CP12 and the TSVs TSV13 and TSV14. Each of the first and second coils may have a shape in which a portion of a closed curve is open. The second coil may be referred to as an inner coil, and the first coil may be referred to as an outer coil. The inner coil may be surrounded by the outer coil. The third conductive connection pattern CP13 may electrically connect the first coil with the second coil.

In some embodiments, in a cross-sectional view of the 3D inductor structure 100d, the conductive patterns P11 and P13 and the TSV TSV11 may be formed to have a stepped structure or a terraced structure. Similarly, in a cross-sectional view, the conductive patterns P12 and P14 and the TSV TSV12 may be formed to have a stepped structure or a terraced structure, the conductive patterns P15 and P17 and the TSV TSV13 may be formed to have a stepped structure or a terraced structure, and the conductive patterns P16 and P18 and the TSV TSV14 may be formed to have a stepped structure or a terraced structure.

In some embodiments, the conductive patterns P17, P18 and CP12 may not be physically separated and may be a single conductive pattern for forming the second coil. Similarly, the conductive patterns P11, P16 and CP13 may not be physically separated and may be a single conductive pattern.

In some embodiments, although not illustrated in FIG. 7, the third conductive connection pattern CP13 may electrically connect the first end 129d of the second conductive pattern P12 with the first end 111d of the fifth conductive pattern P15, and the I/O unit may be electrically connected to the first end 119d of the first conductive pattern P11 and the first end 115d of the sixth conductive pattern P16.

In some embodiments, although not illustrated in FIG. 7, the first and second conductive connection patterns may be included in the first semiconductor die 110d, and the third conductive connection pattern CP13 and the I/O unit may be included in the second semiconductor die 120d. In this example, the first conductive connection pattern CP11 may electrically connect the first end 119d of the first conductive pattern P11 with the first end 129d of the second conductive pattern P12, the second conductive connection pattern CP12 may electrically connect the first end 111d of the fifth conductive pattern P15 with the first end 115d of the sixth conductive pattern P16, and the third conductive connection pattern CP13 may electrically connect the first end (e.g., 121a or 125a) of one of the third and fourth conductive patterns P13 and P14 with the first end (e.g., 121d or 125d) of one of the seventh and eighth conductive patterns P17 and P18.

In some embodiments, although not illustrated in FIG. 7, the first and second semiconductor dies 110d and 120d may include more conductive patterns and more TSVs for forming at least one coil that surrounds the first coil or is surrounded by the second coil. In some embodiments, although not illustrated in FIG. 7, a 3D inductor structure according to some embodiments may further include at least one middle semiconductor die that are disposed between the first semiconductor die 110d (e.g., the bottom semiconductor die) and the second semiconductor die 120d (e.g., the top semiconductor die).

FIG. 9A is a plan view of a stacked semiconductor device according to some embodiments. FIG. 9B is a cross-sectional view of the stacked semiconductor device taken along a line III-III′ of FIG. 9A. Referring to FIGS. 9A and 9B, a stacked semiconductor device 200 includes a first semiconductor die 210 and a plurality of second semiconductor dies 220, 230 and 240. The first semiconductor die 210 includes a first conductive pattern 211, a second conductive pattern 213, a first conductive connection pattern 215 and a first functional circuit 201.

The second conductive pattern 213 is spaced apart from the first conductive pattern 211. The first conductive connection pattern 215 electrically connects a first end of the first conductive pattern 211 with a first end of the second conductive pattern 213. The first functional circuit 201 may be one of various circuits or blocks that perform predetermined operations or functions. For example, the first functional circuit 201 may include a memory, an interface, a digital signal processing circuit, an analog signal processing circuit, etc.

The second semiconductor dies 220, 230 and 240 are sequentially stacked on the first semiconductor die 210. Each of the second semiconductor dies 220, 230 and 240 includes multiple third conductive patterns, multiple fourth conductive patterns, a first TSV, a second TSV and a second functional circuit.

For example, the uppermost semiconductor die 240 may include multiple third conductive patterns 241a, 241b and 241c, multiple fourth conductive patterns 243a, 243b and 243c that are spaced apart from the third conductive patterns 241a, 241b and 241c, first and second TSVs 242a and 244a that penetrate the semiconductor die 240, and a second functional circuit 202c. Similarly, the semiconductor die 220 may include multiple third conductive patterns 221a, 221b and 221c, multiple fourth conductive patterns that are spaced apart from the third conductive patterns 221a, 221b and 221c, first and second TSVs 222a and 224a that penetrate the semiconductor die 220, and a second functional circuit 202a. The semiconductor die 230 may include multiple third conductive patterns 231a, 231b and 231c, multiple fourth conductive patterns that are spaced apart from the third conductive patterns 231a, 231b and 231c, first and second TSVs 232a and 234a that penetrate the semiconductor die 230, and a second functional circuit 202b. Each of the second functional circuits 202a, 202b and 202c may be one of various circuits or blocks that perform predetermined operations or functions.

In some embodiments, the second semiconductor dies 220, 230 and 240 may be homogeneous. In other words, structures of the second semiconductor dies 220, 230 and 240 may be substantially the same as one another. The first semiconductor die 210 and the second semiconductor dies 220, 230 and 240 may be heterogeneous. In other words, a structure of the first semiconductor die 210 may be different from the structures of the second semiconductor dies 220, 230 and 240.

In the stacked semiconductor device 200 according to some embodiments, one of the third conductive patterns included in each of the second semiconductor dies 220, 230 and 240 is selected as a first selection pattern. For each of the second semiconductor dies 220, 230 and 240, the first selection pattern among the third conductive patterns is electrically connected to the first conductive pattern 211 by the first TSV of that second semiconductor die.

For example, a first selection pattern 221c included in the semiconductor die 220 may be electrically connected to the first conductive pattern 211 by the first TSV 222a. Similarly, a first selection pattern 231b included in the semiconductor die 230 may be electrically connected to the first conductive pattern 211 by the first TSV 232a, and a first selection pattern 241a included in the semiconductor die 240 may be electrically connected to the first conductive pattern 211 by the first TSV 242a. In FIG. 9B, the first selection patterns 221c, 231b and 241a and the first TSV 222a, 232a and 242a are filled with diagonal lines.

In some embodiments, each of the second semiconductor dies 220, 230 and 240 may further include at least one first wiring and at least one first contact that electrically connect the first TSV with the first selection pattern.

For example, the semiconductor die 220 may further include a first wiring 225a and a first contact 226a that electrically connect the first TSV 222a with the first selection pattern 221c. The semiconductor die 230 may further include a first wiring 235a and a first contact 236a that electrically connect the first TSV 232a with the first selection pattern 231b. The semiconductor die 240 may further include a first wiring 245a and a first contact 246a that electrically connect the first TSV 242a with the first selection pattern 241a. Although the first selection patterns 221c, 231b and 241a do not overlap one another, the first selection patterns 221c, 231b and 241a may be electrically connected to the first conductive pattern 211 by the first TSVs 222a, 232a and 242a, the first wirings 225a, 235a and 245a and the first contacts 226a, 236a and 246a.

Although not illustrated in FIGS. 9A and 9B, one of the fourth conductive patterns included in each of the second semiconductor dies 220, 230 and 240 is selected as a second selection pattern. For each of the second semiconductor dies 220, 230 and 240, the second selection pattern among the fourth conductive patterns is electrically connected to the second conductive pattern 213 by the second TSV of that second semiconductor die. For example, a second selection pattern 243a included in the semiconductor die 240 may be electrically connected to the second conductive pattern 213 by the second TSV 244a. Arrangements and connections of the second selection patterns and the second TSVs 224a, 234a and 244a may be substantially the same as those of the first selection patterns 221c, 231b and 241a and the first TSVs 222a, 232a and 242a. In some embodiments, each of the second semiconductor dies 220, 230 and 240 may further include at least one second wiring and at least one second contact that electrically connect the second TSV with the second selection pattern.

In some embodiments, a coil may be formed by electrical connections of the conductive patterns 211, 213 and 215 in the first semiconductor dies 210, and the first selection patterns 221c, 231b and 241a, the first TSVs 222a, 232a and 242a, the second selection patterns and the second TSVs 224a, 234a and 244a in the second semiconductor dies 220, 230 and 240. The coil may further include the first wirings 225a, 235a and 245a, the first contacts 226a, 236a and 246a, the second wirings and the second contacts. The coil in FIGS. 9A and 9B may have a structure similar to that of the coil in FIG. 3.

In some embodiments, in a plan view of the stacked semiconductor device 200 including the semiconductor dies 210, 220, 230 and 240, the coil has a shape in which a portion of a closed curve is open. In some embodiments, in a cross-sectional view of the stacked semiconductor device 200, the conductive patterns 211, 221c, 231b and 241a and the TSVs 222a, 232a and 242a may be formed to have a stepped structure or a terraced structure. The stepped structure may further include the wirings 225a, 235a and 245a and the contacts 226a, 236a and 246a.

In some embodiments, each of the second semiconductor dies 220, 230 and 240 may further include a fuse unit and an I/O unit. The fuse unit may be connected to a first end of a first I/O pattern among the third conductive patterns and a first end of a second I/O pattern among the fourth conductive patterns. The I/O unit may be connected to the fuse unit. The fuse unit may include at least one fuse (e.g., an electrical fuse (e-fuse), an anti-fuse, etc.) and may control an electrical connection between the I/O unit and the first and second I/O patterns based on an enable signal EN. For example, the first I/O pattern may be one of the third conductive patterns farthest away from the first conductive pattern 211, and the second I/O pattern may be one of the fourth conductive patterns farthest away from the second conductive pattern 213.

For example, the semiconductor die 240 may further include a fuse unit 250c connected to a first end of a first I/O pattern 241a and a first end of a second I/O pattern 243a, and an I/O unit 260c connected to the fuse unit 250c. Similarly, the semiconductor die 220 may further include a fuse unit 250a connected to a first end of a first I/O pattern 221a and a first end of a second I/O pattern, and an I/O unit 260a connected to the fuse unit 250a. The semiconductor die 230 may further include a fuse unit 250b connected to a first end of a first I/O pattern 231a and a first end of a second I/O pattern, and an I/O unit 260b connected to the fuse unit 250b.

In some embodiments, the I/O unit 260c that is included in the uppermost semiconductor die 240 among the second semiconductor dies 220, 230 and 240 may be enabled based on the fuse unit 250c and may be electrically connected to the first end of the first I/O pattern 241a and the first end of the second I/O pattern 243a. The I/O units 260a and 260b that are included in the semiconductor dies 220 and 230 other than the uppermost semiconductor die 240 may be disabled based on the fuse units 250a and 250b, respectively, and may not be electrically connected to the first I/O patterns 221a and 231a and the second I/O patterns. In other words, the I/O unit 260c that is directly connectable to the coil may be enabled by the fuse unit 250c, and the I/O units 260a and 260b that are not able to be directly connected to the coil may be disabled by the fuse units 250a and 250b. In FIG. 9B, the enabled I/O unit 260c and fuse unit 250c are filled with diagonal lines to represent the units being enabled. The coil and the I/O unit 260c in FIGS. 9A and 9B may have a configuration similar to that of the coil and the I/O unit 102 in FIG. 3.

In some embodiments, in the uppermost semiconductor die 240, the first and second selection patterns 241a and 243b may be substantially the same or the same as the first and second I/O patterns 241a and 243b, respectively. In the semiconductor dies 220 and 230 other than the uppermost semiconductor die 240, the first selection patterns 221c and 231b may be different from the first I/O patterns 221a and 231a, respectively, and the second selection patterns may be different from the second I/O patterns, respectively. In other words, the I/O unit 260c included in the semiconductor die 240 where the selection patterns are substantially the same as the I/O patterns may be enabled, and the I/O units 260a and 260b included in the semiconductor dies 220 and 230 where the selection patterns are different from the I/O patterns may be disabled.

In some embodiments, the stacked semiconductor device 200 may be a memory device. For example, each of the functional circuits may be a memory cell array disposed in a memory region, and the conductive patterns and the TSVs may be disposed in a peripheral region surrounding the memory region. In other embodiments, the stacked semiconductor device 200 may be any semiconductor device. For example, the conductive patterns and the TSVs may be disposed in a peripheral region surrounding the functional circuits.

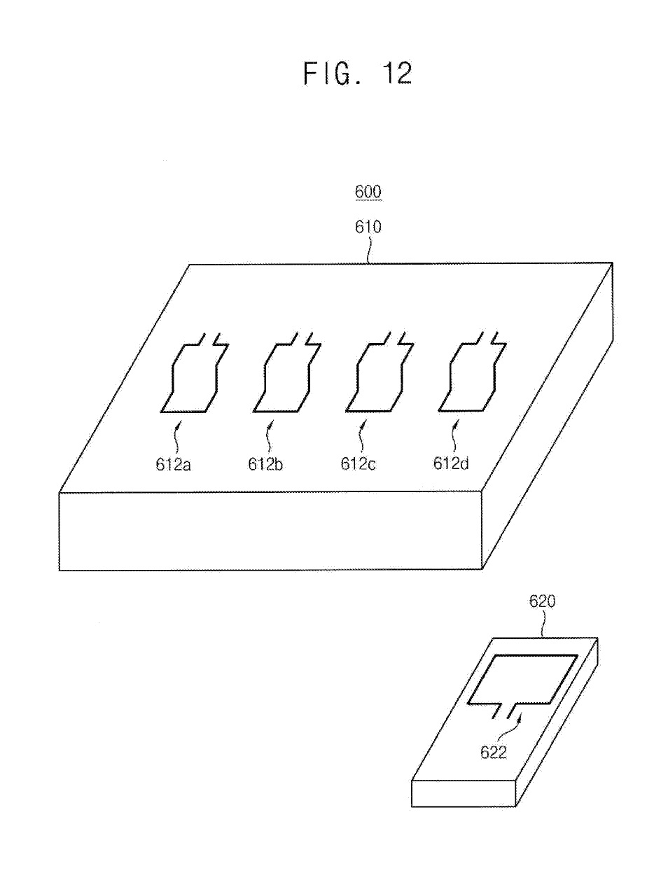

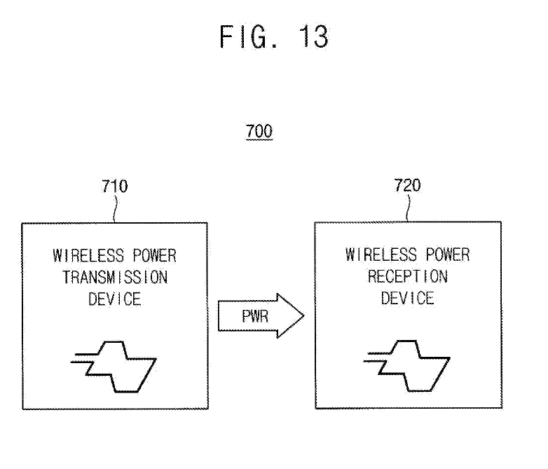

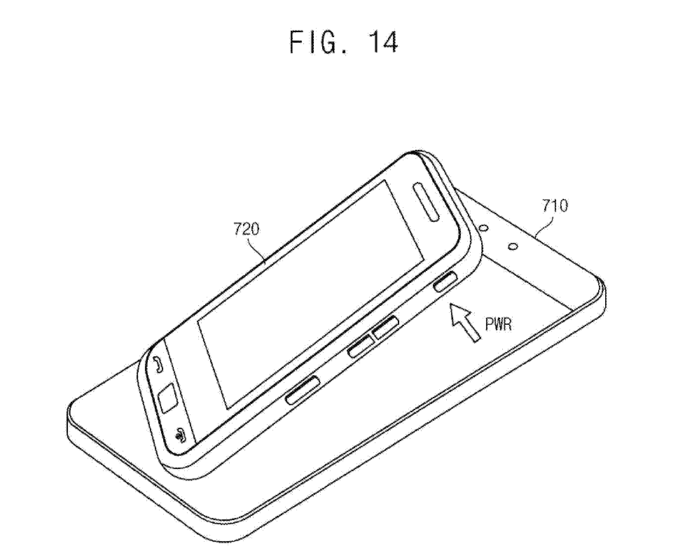

In some embodiments, as will be described with reference to FIGS. 11 and 12, the coil in the stacked semiconductor device 200 may operate as a data transmitter that transmits data from at least one functional circuit to an external device, and/or a data receiver that receives data from an external device and transfers the received data to at least one functional circuit. In other embodiments, as will be described with reference to FIGS. 13 and 14, the coil in the stacked semiconductor device 200 may operate as a power receiver that supplies power from an external device to at least one functional circuit based on an electromagnetic induction, and/or a power transmitter that provides power to an external device based on the electromagnetic induction.

Although FIGS. 9A and 9B illustrate an example where the second semiconductor dies 220, 230 and 240 are homogeneous and the first semiconductor die 210 and the second semiconductor dies 220, 230 and 240 are heterogeneous, in other embodiments, all of stacked semiconductor dies may be homogeneous, or some of the second semiconductor dies and others of the second semiconductor dies may be heterogeneous. In addition, although FIGS. 9A and 9B illustrate an example where each of the second semiconductor dies 220, 230 and 240 includes a single wiring (e.g., 225a) and a single contact (e.g., 226a) for connecting the first selection pattern with the first TSV, the number of the wirings and the contacts included in each of the second semiconductor dies 220, 230 and 240 may be different in other embodiments.

In some embodiments, the number of the second semiconductor dies stacked on the first semiconductor die, shapes of the conductive patterns and the TSVs, the number of the conductive patterns and the TSVs, and arrangements of the conductive patterns and the TSVs may be different such that the coil having a shape in which a portion of a closed curve is open and a stepped structure is formed in the stacked semiconductor device. In some embodiments, as described with reference to FIG. 7, at least one inner coil and/or at least one outer coil may be further formed in the stacked semiconductor device.

The stacked semiconductor device 200 according to some embodiments may include a 3D inductor structure that is formed by the conductive patterns 211, 213, 215, 221c, 231b, 241a and 241b and the TSVs 222a, 224a, 232a, 234a, 242a and 244a. Accordingly, the stacked semiconductor device 200 may have a relatively small size and may be easily manufactured. In addition, the stacked semiconductor device 200 may efficiently transmit or receive data and/or power based on the 3D inductor structure.

FIG. 10A is a plan view of a stacked semiconductor device according to some embodiments. FIG. 10B is a cross-sectional view of the stacked semiconductor device taken along a line IV-IV′ of FIG. 10A. Referring to FIGS. 10A and 10B, a stacked semiconductor device 300 includes a first semiconductor die 310 and multiple second semiconductor dies 320, 330 and 340.

The stacked semiconductor device 300 of FIGS. 10A and 10B may be substantially the same as the stacked semiconductor device 200 of FIGS. 9A and 9B, except that arrangements and connections of a first conductive connection pattern 349 and an I/O unit 360 are different, and a fuse unit and an I/O unit are omitted in each of the second semiconductor dies 320, 330 and 340. In particular, the conductive patterns 311 and 313 in the first semiconductor die 310, the first selection patterns 321c, 331b and 341a, the first TSVs 322a, 332a and 342a, the second selection patterns and the second TSVs 324a, 334a and 344a in the second semiconductor dies 320, 330 and 340, the first wirings 325a, 335a and 345a, the first contacts 326a, 336a and 346a, the second wirings and the second contacts may be the same or similar to the corresponding structures described with respect to FIGS. 9A and 9B. However, in the stacked semiconductor device 300 according to some embodiments, the uppermost semiconductor die 340 among the second semiconductor dies 320, 330 and 340 may further include the first conductive connection pattern 349. The first conductive connection pattern 349 electrically connects a first end of the first selection pattern 341a with a first end of the second selection pattern 343a.

In some embodiments, a coil may be similar to that described with respect to FIGS. 9A and 9B. In other embodiments, the coil in FIGS. 10A and 10B may have a structure similar to that of the coil in FIG. 1 or FIG. 5. In addition, the coil and the I/O unit 360 in FIGS. 10A and 10B may have a configuration similar to that of the coil and the I/O unit IO1 in FIG. 1 or that of the coil and the I/O unit 103 in FIG. 5.

FIG. 11 is a block diagram illustrating a data transceiving system according to some embodiments. Referring to FIG. 11, a data transceiving system 500 may include a first data transceiver 510 and a second data transceiver 520. The first data transceiver 510 may include a first coil 512, and the second data transceiver 520 may include a second coil 522.

When transmission data DIN is provided to the first coil 512 of the first data transceiver 510, voltage fluctuation of the first coil 512 may be transferred to the second coil 522 as an electrical signal by magnetic coupling between the first coil 512 and the second coil 522. The electrical signal transferred to the second coil 522 may be output as reception data DOUT through an output terminal connected to the second coil 522. A near field contactless communication performed in this manner may be referred to as an inductive coupling communication.

The first data transceiver 510 may include a stacked semiconductor device according to some embodiments, and the first coil 512 may be implemented as a 3D inductor structure according to some embodiments. Accordingly, the first data transceiver 510 including the first coil 512 may have a relatively small size and may be more easily manufactured. In addition, the first data transceiver 510 may more efficiently transmit data using the first coil 512.

Although FIG. 11 illustrates an example where the first data transceiver 510 operates as a data transmitter and the second data transceiver 520 operates as a data receiver, the first data transceiver 510 may operate as a data receiver and the second data transceiver 520 may operate as a data transmitter. Although not illustrated in FIG. 11, the second coil 522 included in the second data transceiver 520 may also be implemented as a 3D inductor structure described herein according to some embodiments.

FIG. 12 is a block diagram illustrating a test system according to some embodiments. Referring to FIG. 12, a test system 600 may include a device 610 to be tested and a test data provider 620. The device 610 to be tested may include multiple coils 612a, 612b, 612c and 612d. The test data provider 620 may include a coil 622. For example, the test data provider 620 may be a test probe that is connected to a test data generator.

When test data is provided to the coil 622 of the test data provider 620 after the test data provider 620 is moved nearest to one coil (e.g., 612a) of the device 610, the one coil (e.g., 612a) may receive the test data by the inductive coupling communication. A testing operation may be performed based on the received test data, the one coil (e.g., 612a) may output test result data representing a result of the testing operation, and the coil 622 may receive the test result data by the inductive coupling communication. It may be determined, based on the test result data, whether the testing operation succeeds or fails. The testing operation may be performed for all of the coils 612a, 612b, 612c and 612d.

The device 610 may include a stacked semiconductor device according to some embodiments, and each of the coils 612a, 612b, 612c and 612d may be implemented as a 3D inductor structure according to some embodiments. Accordingly, the device 610 including the coils 612a, 612b, 612c and 612d may have a relatively small size and may be easily manufactured. In addition, the device 610 may efficiently receive the test data and transmit the test result data based on the coils 612a, 612b, 612c and 612d, and thus the testing operation for the device 610 may be efficiently and rapidly performed in a non-contact manner.

Although FIG. 12 illustrates an example where the test data provider 620 includes a single coil 622, the test data provider may include multiple coils. For example, the number of coils included in the test data provider may be substantially the same as the number of coils included in the device to be tested, and then a time for the testing operation may be further reduced. Although not illustrated in FIG. 12, the coil 622 included in the test data provider 620 may also be implemented as a 3D inductor structure according to some embodiments.

FIG. 13 is a block diagram illustrating a wireless power transmission system according to some embodiments. FIG. 14 is a diagram illustrating an example of the wireless power transmission system of FIG. 13. Referring to FIGS. 13 and 14, a wireless power transmission system 700 may include a wireless power transmission device 710 and a wireless power reception device 720. In some embodiments, as illustrated in FIG. 14, the wireless power reception device 720 may be implemented as a smart phone. In other some embodiments, the wireless power reception device 720 may be implemented as any mobile device, such as a mobile phone, a tablet computer, a laptop computer, a personal digital assistants (PDA), a portable multimedia player (PMP), a digital camera, a portable game console, a music player, a camcorder, a video player, a navigation system, etc. The mobile device may further include a wearable device, an internet of things (IoT) device, an internet of everything (IoE) device, an e-book, a virtual reality (VR) device, a robotic device, etc.

The wireless power transmission device 710 may transmit power PWR to the wireless power reception device 720 in a non-contact manner.

In some embodiments, the wireless power transmission device 710 may include a source coil that receives the power PWR from a source voltage and transmits the power PWR externally through electromagnetic induction. The wireless power transmission device 710 may further include a resonance coil that transmits the power PWR externally based on a magnetic resonance. For example, the source coil and the resonance coil may be inductively coupled to each other. Here, the inductive coupling may represent that multiple coils are coupled through mutual inductance, at least a part of magnetic flux generated by current flowing through a first coil is linked to a second coil, and thus a current is induced in the second coil.

In some embodiments, the wireless power reception device 720 may include a load coil that receives the power PWR based on the electromagnetic induction. The wireless power reception device 720 may further include a resonance coil that receives the power PWR based on the magnetic resonance.

At least one of the wireless power transmission device 710 and the wireless power reception device 720 may include at least one coil that is implemented as a 3D inductor structure according to some embodiments. Accordingly, the wireless power transmission device 710 and the wireless power reception device 720 may have a relatively small size and may be easily manufactured. In addition, the power PWR may be more efficiently and rapidly transmitted or received in the wireless power transmission system 700.

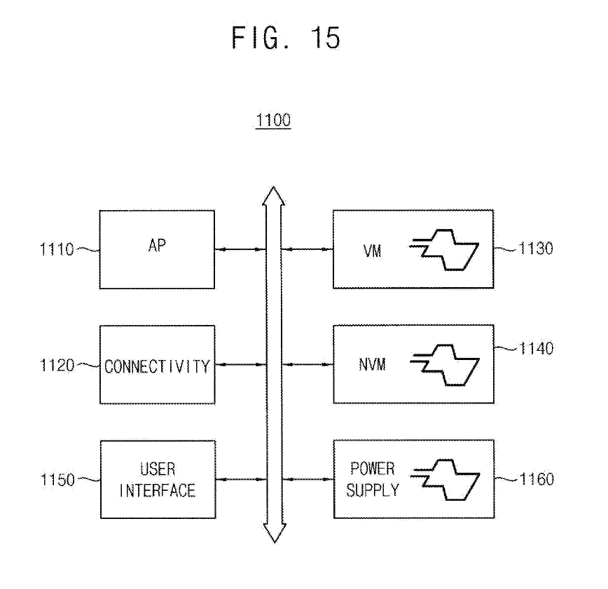

FIG. 15 is a block diagram illustrating a mobile system according to some embodiments. Referring to FIG. 15, a mobile system 1100 may include an application processor (AP) 1110, a connectivity module 1120, a first memory device 1130, a second memory device 1140, a user interface 1150 and a power supply 1160.

The AP 1110 may perform various computational functions such as, for example, particular calculations and task executions. The AP 1110 may execute an operating system (OS) to drive the mobile system 1100, and may execute various applications for providing an internet browser, a game, a video, a camera, etc.

In some embodiments, the AP 1110 may include a single processor core or multiple processor cores. In some embodiments, the AP 1110 may further include a cache memory that may be located inside or outside the AP 1110.

The connectivity module 1120 may communicate with an external device (not shown). The connectivity module 1120 may communicate using one of various types of communication interfaces such as, for example, universal serial bus (USB), Ethernet, near field communication (NFC), radio frequency identification (RFID), a mobile telecommunication like 4th generation (4G) and long term evolution (LTE), a memory card interface, or the like. In some embodiments, the connectivity module 1120 may include a baseband chipset, and may support one or more of a number of different communication technologies such as, for example, global system for mobile communications (GSM), general packet radio service (GPRS), wideband code division multiple access (WCDMA), high speed packet access (HSPA), etc.

The first and second memory devices 1130 and 1140 may operate as a data storage for data processed by the AP 1110 or a working memory in the mobile system 1100. For example, the first and second memory devices 1130 and 1140 may store a boot image for booting the mobile system 1100, a file system for the operating system to drive the mobile system 1100, a device driver for an external device connected to the mobile system 1100, and/or an application executed on the mobile system 1100.

In some embodiments, the first memory device 1130 may include a volatile memory such as, for example, a dynamic random access memory (DRAM), a static random access memory (SRAM), a mobile DRAM, a double data rate (DDR) synchronous DRAM (SDRAM), a low power DDR (LPDDR) SDRAM, a graphic DDR (GDDR) SDRAM, or a Rambus DRAM (RDRAM), etc. In some embodiments, the second memory module 1140 may include a nonvolatile memory such as, for example, an electrically erasable programmable read-only memory (EEPROM), a flash memory, a phase random access memory (PRAM), a resistive random access memory (RRAM), a nano floating gate memory (NFGM), a polymer random access memory (PoRAM), a magnetic random access memory (MRAM), a ferroelectric random access memory (FRAM), a thyristor random access memory (TRAM), etc.

The first and second memory devices 1130 and 1140 may include a stacked semiconductor device according to some embodiments, and may include a coil that is implemented as a 3D inductor structure according to some embodiments. Accordingly, the first and second memory devices 1130 and 1140 may have a relatively small size and may be more easily manufactured. In addition, the first and second memory devices 1130 and 1140 may more efficiently transmit or receive data based on the coil.

The user interface 1150 may include at least one input device such as, for example, a keypad, a button, a microphone, a touch screen, etc., and/or at least one output device such as, for example, a speaker, a display device, haptic device, etc. The power supply 1160 may provide power to the mobile system 1100.

The power supply 1160 may include a coil that is implemented as a 3D inductor structure according to some embodiments. Accordingly, the power supply 1160 may have a relatively small size and may be more easily manufactured. In addition, power may be efficiently and rapidly transmitted or received in the mobile system 1100.

In some embodiments, the stacked semiconductor devices 200 and 300, the mobile system 1100 and/or components thereof may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi-chip package (MCP), wafer-level fabricated package (WFP), or wafer-level processed stack package (WSP).

Embodiments may be applied to various devices and systems to include the 3D inductor structure and the stacked semiconductor device. For example, embodiments may include systems such as be a mobile phone, a smart phone, a PDA, a PMP, a digital camera, a camcorder, a PC, a server computer, a workstation, a laptop computer, a digital TV, a set-top box, a portable game console, a navigation system, etc.

The foregoing is illustrative of embodiments and is not to be construed as limiting thereof. Although particular embodiments have been described, those skilled in the art will readily appreciate that many modifications are possible in other embodiments without materially departing from the teachings and advantages of the present disclosure. Accordingly, all such modifications are intended to be included within the scope of the embodiments defined in the claims.

What is claimed is:

1. A three-dimensional (3D) inductor structure comprising:
a first semiconductor die including:
a first conductive pattern; and
a second conductive pattern spaced apart from the first conductive pattern;
a second semiconductor die stacked on the first semiconductor die, the second semiconductor die including:
a third conductive pattern;
a fourth conductive pattern spaced apart from the third conductive pattern;
a first through-substrate via (TSV) penetrating the second semiconductor die and electrically connecting the first conductive pattern with the third conductive pattern; and
a second TSV penetrating the second semiconductor die and electrically connecting the second conductive pattern with the fourth conductive pattern, and
a first conductive connection pattern included in the first semiconductor die and electrically connecting a first end of the first conductive pattern with a first end of the second conductive pattern, or included in the second semiconductor die and electrically connecting a first end of the third conductive pattern with a first end of the fourth conductive pattern.

2. The 3D inductor structure of claim 1, wherein:
the first, second, third and fourth conductive patterns, the first and second TSVs and the first conductive connection pattern form a coil, and
in a plan view, the coil has a shape in which a portion of a closed curve is open.

3. The 3D inductor structure of claim 2, wherein, in a cross-sectional view, the first conductive pattern, the first TSV and the third conductive pattern are formed to have a stepped structure.

4. The 3D inductor structure of claim 1, wherein:
the first conductive connection pattern is included in the second semiconductor die and electrically connects the first end of the third conductive pattern with the first end of the fourth conductive pattern; and
the first semiconductor die further includes an inductive coupling input/output (I/O) unit electrically connected to the first end of the first conductive pattern and the first end of the second conductive pattern.

5. The 3D inductor structure of claim 1, wherein:
the first conductive connection pattern is included in the first semiconductor die and electrically connects the first end of the first conductive pattern with the first end of the second conductive pattern; and
the second semiconductor die further includes an inductive coupling input/output (I/O) unit electrically connected to the first end of the third conductive pattern and the first end of the fourth conductive pattern.

6. The 3D inductor structure of claim 1, further comprising:
a third semiconductor die between the first semiconductor die and the second semiconductor die, the third semiconductor die including:
a fifth conductive pattern;
a sixth conductive pattern spaced apart from the fifth conductive pattern;
a third TSV penetrating the third semiconductor die; and
a fourth TSV penetrating the third semiconductor die,
wherein the first TSV electrically connects a first end of the fifth conductive pattern with a second end of the third conductive pattern, and the third TSV electrically connects a second end of the fifth conductive pattern with a second end of the first conductive pattern,
wherein the second TSV electrically connects a first end of the sixth conductive pattern with a second end of the fourth conductive pattern, and the fourth TSV electrically connects a second end of the sixth conductive pattern with a second end of the second conductive pattern.

7. The 3D inductor structure of claim 1,
wherein the first semiconductor die further includes:
a fifth conductive pattern spaced apart from the first and second conductive patterns; and
a sixth conductive pattern spaced apart from the first, second and fifth conductive patterns;
wherein the second semiconductor die further includes:
a seventh conductive pattern spaced apart from the third and fourth conductive patterns;
an eighth conductive pattern spaced apart from the third, fourth and seventh conductive patterns;
a third TSV penetrating the second semiconductor die and electrically connecting the fifth conductive pattern with the seventh conductive pattern; and
a fourth TSV penetrating the second semiconductor die and electrically connecting the sixth conductive pattern with the eighth conductive pattern,
the 3D inductor structure further comprising:
a second conductive connection pattern included in the first semiconductor die to electrically connect a first end of the fifth conductive pattern with a first end of the sixth conductive pattern, or included in the second semiconductor die to electrically connect a first end of the seventh conductive pattern with a first end of the eighth conductive pattern; and
a third conductive connection pattern included in the first semiconductor die to electrically connect the first end of one of the first and second conductive patterns with the first end of one of the fifth and sixth conductive patterns, or included in the second semiconductor die to electrically connect the first end of one of the third and fourth conductive patterns with the first end of one of the seventh and eighth conductive patterns.

8. The 3D inductor structure of claim 7, wherein:
the first conductive connection pattern is included in the second semiconductor die and electrically connects the first end of the third conductive pattern with the first end of the fourth conductive pattern;
the second conductive connection pattern is included in the second semiconductor die and electrically connects the first end of the seventh conductive pattern with the first end of the eighth conductive pattern; and
the third conductive connection pattern is included in the first semiconductor die and electrically connects the first end of one of the first and second conductive patterns with the first end of one of the fifth and sixth conductive patterns.

9. The 3D inductor structure of claim 8, wherein:
the third conductive connection pattern electrically connects the first end of the first conductive pattern with the first end of the sixth conductive pattern; and
the first semiconductor die further includes an inductive coupling I/O unit electrically connected to the first end of the second conductive pattern and the first end of the fifth conductive pattern.

10. The 3D inductor structure of claim 7, wherein:
the fifth, sixth, seventh and eighth conductive patterns, the third and fourth TSVs and the second conductive connection pattern form an inner coil;
the first, second, third and fourth conductive patterns, the first and second TSVs and the first conductive connection pattern form an outer coil; and
the inner coil is surrounded by the outer coil.

11. A stacked semiconductor device comprising:
a first semiconductor die including:
a first conductive pattern;
a second conductive pattern spaced apart from the first conductive pattern;
a first conductive connection pattern electrically connecting a first end of the first conductive pattern with a first end of the second conductive pattern; and
a first functional circuit; and
a plurality of second semiconductor dies sequentially stacked on the first semiconductor die, each of the second semiconductor dies including:
a plurality of third conductive patterns;
a plurality of fourth conductive patterns spaced apart from the third conductive patterns;
a first through-substrate via (TSV) penetrating each of the second semiconductor dies;
a second TSV penetrating each of the second semiconductor dies; and
a second functional circuit;
wherein:
a first selection pattern among the third conductive patterns is electrically connected to the first conductive pattern by the first TSV; and
a second selection pattern among the plurality of fourth conductive patterns is electrically connected to the second conductive pattern by the second TSV.

12. The stacked semiconductor device of claim 11, wherein:
the first and second conductive patterns, the first conductive connection pattern, the first and second selection patterns and the first and second TSVs form a coil; and
in a plan view, the coil has a shape in which a portion of a closed curve is open.

13. The stacked semiconductor device of claim 12, wherein, in a cross-sectional view, the first conductive pattern, the first TSV and the first selection pattern are formed to have a stepped structure.

14. The stacked semiconductor device of claim 11, wherein each of the second semiconductor dies further includes:
a fuse unit connected to a first end of a first input/output (I/O) pattern among the third conductive patterns and a first end of a second I/O pattern among the fourth conductive patterns; and
an inductive coupling I/O unit connected to the fuse unit;
wherein:
the inductive coupling I/O unit included in an uppermost semiconductor die among the second semiconductor dies is enabled based on the fuse unit of the uppermost semiconductor die and is electrically connected to the first end of the first I/O pattern and the first end of the second I/O pattern of the uppermost semiconductor die; and
the inductive coupling I/O unit included in a semiconductor die other than the uppermost semiconductor die is disabled based on the fuse unit of that semiconductor die and is electrically not connected to the first end of the first I/O pattern and the first end of the second I/O pattern of that semiconductor die.

15. The stacked semiconductor device of claim 11, wherein each of the second semiconductor dies further includes:
a first wiring and a first contact electrically connecting the first TSV with the first selection pattern; and
a second wiring and a second contact electrically connecting the second TSV with the second selection pattern.

16. A stacked semiconductor device comprising:
a plurality of semiconductor dies;
a plurality of through-substrate vias (TSV) penetrating at least one of the semiconductor dies;
a plurality of conductive patterns, wherein each of the semiconductor dies includes at least two of the conductive patterns; and
a first conductive connection pattern included in one of the semiconductor dies that electrically connects a first two of the conductive patterns;
wherein:
each of the TSVs electrically connects a corresponding second two of the conductive patterns; and
the TSVs, the conductive patterns, and the first conductive connection pattern are electrically connected in series.

17. The stacked semiconductor device of claim 16, wherein the semiconductor dies comprise at least three semiconductor dies.

18. The stacked semiconductor device of claim 16, wherein an uppermost semiconductor die of the semiconductor dies comprises:
a fuse unit electrically connected to two of the at least two of the conductive patterns within the uppermost semiconductor die; and
an input/output (I/O) unit enabled based on the fuse unit.

19. The stacked semiconductor device of claim 16, wherein:
the semiconductor dies comprise a lowermost semiconductor die; and
the semiconductor dies other than the lowermost semiconductor die are identical.

20. The stacked semiconductor device of claim 16, wherein:
the semiconductor dies comprise a lowermost semiconductor die; and
each of the semiconductor dies other than the lowermost semiconductor die comprises a contact and a wiring, wherein one of the conductive patterns of that semiconductor die is electrically connected to one of the TSVs of that semiconductor die through the contact and the wiring.
